(19) United States
(12) Patent Application Publication
(10) Pub. No.: US 2024/0006891 A1
(43) Pub. Date: Jan. 4, 2024

(54) TWO-STAGE SELF-ORGANIZING OPTIMIZED AGGREGATION METHOD AND SYSTEM FOR DISTRIBUTED RESOURCES OF VIRTUAL POWER PLANT (VPP)

(71) Applicant: Changsha University of Science and Technology, Hunan (CN)

(72) Inventors: Dongqi LIU, Hunan (CN); Xiangjun ZENG, Hunan (CN); Yongpeng SHEN, Hunan (CN); Yong XU, Hunan (CN); Hao YAO, Hunan (CN); Kai DING, Hunan (CN); Wei DENG, Hunan (CN)

(21) Appl. No.: 18/343,169

(22) Filed: Jun. 28, 2023

(30) Foreign Application Priority Data
Jun. 30, 2022 (CN) 2022107593765

(51) Int. Cl. H02J 3/38; H02J 3/46; G05B 13/02; G05B 13/04

(52) U.S. Cl. CPC H02J 3/381; H02J 3/466; G05B 13/027; G05B 13/042; H02J 2203/20; H02J 2300/20

(57) ABSTRACT

Provided is a two-stage self-organizing optimized aggregation method and system for distributed resources of a virtual power plant. First-stage aggregation oriented to a distribution transformer area is completed by taking a natural physical cluster composed of distributed energy resources in the distribution transformer area as a first stage, performing aggregation by using an edge computing server deployed in the distribution transformer area, constructing a generalized transformer area load model including wind power, photovoltaic power, and a load, aggregating distributed gas turbines and generators of small hydropower stations in the distribution transformer area into a unified virtual synchronous generator model, aggregating distributed energy storage devices in the distribution transformer area into a centralized virtual energy storage model; second-stage aggregation across distribution transformer areas is completed by uploading all parameters of the generalized transformer area load model, the virtual synchronous generator model, and the virtual energy storage model to a cloud end.

### CROSS REFERENCE TO RELATED APPLICATION

This patent disclosure claims the benefit and priority of Chinese Patent Application No. 2022107593765, filed with the China National Intellectual Property Administration on Jun. 30, 2022, the disclosure of which is incorporated by reference herein in its entirety as part of the present disclosure.

### TECHNICAL FIELD

The present disclosure relates to the technical field of a virtual power plant (VPP), and specifically, to a two-stage self-organizing optimized aggregation method and system for distributed resources of a VPP.

### BACKGROUND

As distributed energy resources (DERs) such as a wind power resource, a photovoltaic resource, and an electric automobile grow by leaps, there will be massive DERs connected to a distribution network in various forms in the future. Although the DERs make up an increasing proportion in the distribution network, advantages of the DERs are difficult to be fully and effectively utilized. The DERs have high dispersion, uncertainty, and heterogeneity, which makes it difficult for a large number of small-capacity DERs such as a distributed power supply, a controllable load, and an electric automobile to directly participate in regulation of a power grid. For an indirect regulation mode based on an electricity price, due to a small capacity, each individual DER generally has a small impact on a power system, and often achieves a small economic benefit through participation in the regulation of the power grid. Therefore, the individual DER has low enthusiasm for participating in the regulation. For a direct regulation mode in which a DER directly participates in system scheduling, a system operator needs to solve a complex high-dimensional optimization model, which brings a large computational burden, thereby reducing operational efficiency and failing to ensure efficient and orderly operation of the power system. Therefore, resource aggregation is a key to regulate the DERs in the distribution network and improve energy utilization. As an effective means of aggregating the DERs, a VPP utilizes advanced metering, communication, control, and other technologies to achieve energy aggregation, energy supply, energy consumption, and energy storage without changing grid-connected modes and geographical locations of the DERs, effectively connects the DERs and the power system to achieve resource integration, distribution, and reorganization, and directly participates in scheduling and operation of the power system as an aggregation entity. The VPP is an important way for a smart grid to achieve interaction and intelligentization on an energy supply side.

### SUMMARY

In view of this, the present disclosure provides a two-stage self-organization optimized aggregation method and system for distributed resources of a VPP.

The present disclosure resolves the technical problems with following technical solutions.

A two-stage self-organizing optimized aggregation method for distributed resources of a VPP includes following steps:
1) conducting first-stage aggregation oriented to a distribution transformer area, which specifically includes following steps:
S100: taking a natural physical cluster composed of DERs in the distribution transformer area as a first stage, and performing aggregation by using an edge computing server deployed in the distribution transformer area;
S200: performing uncertainty modeling for power outputs of wind and solar energy in the entire distribution transformer area and a load curve of the distribution transformer area in the edge computing server based on historical data retrieved from a cloud end and a deep Bayesian network, and constructing an hourly prediction model;
S300: constructing, based on the hourly prediction model, a generalized transformer area load model including wind power, photovoltaic power, and a load;
S400: aggregating distributed gas turbines and generators of small hydropower stations in the distribution transformer area into a unified mathematical model for a power output of a virtual synchronous generator; and
S500: aggregating distributed energy storage devices in the distribution transformer area into a mathematical model for a capacity of a virtual centralized energy storage device; and
2) conducting second-stage aggregation across distribution transformer areas: uploading all parameters of the generalized transformer area load model, the virtual synchronous generator model, and the virtual energy storage model to the cloud end for the second-stage aggregation.

As a further improvement, the step S400 includes following steps:
S401: accumulating an upward ramp rate Ramp_{i,up} of a generator numbered i to obtain an upward rate Ramp_{sum,up} of the virtual synchronous generator, and accumulating a downward ramp rate Ramp_{i,down} of the generator numbered i to obtain a downward ramp rate Ramp_{sum,down} of the virtual synchronous generator, where Ramp_{sum,up}=Σᵢ₌₁^{N}Ramp_{i,up}, Ramp_{sum,down}=Σᵢ₌₁^{N}Ramp_{i,down}, and N is a positive integer greater than 0;
S402: calculating upper and lower limits of a power output of a corresponding virtual synchronous generator at a time point t based on upward and downward ramp rates of each generator, where P_{i,max}(t)=Pᵢ(t−1)+Δt×Rampᵢₘₚ, P_{i,min}(t)=Pᵢ(t−1)−Δt×Ramp_{i,down}, P_{i,max}(t)≤P_{i,max}, P_{i,min}(t)≤P_{i,min}, P_{i,max}(t) represents an upper limit of a power output of an i^{th} virtual synchronous generator at the time point t, P_{i,min}(t) represents a lower limit of the power output of the i^{th} virtual synchronous generator at the time point t, Δt represents a time difference between a previous time point and a current time point, Pᵢ(t−1) represents a power output of the virtual synchronous generator at the previous time point, and P_{i,max} and P_{i,min} respectively represent maximum upper and lower limits of a corresponding power output of the i^{th} virtual synchronous generator; and
S403: accumulating upper and lower limits of a power output of each generator at the time point t to obtain a limit value of a total power output of the corresponding virtual synchronous generator at the time point t, namely, Pₘₐₓ(t)=Σᵢ₌₁^{N}P_{i,max}(t), Pₘᵢₙ(t)=Σᵢ₌₁^{N}P_{i,min}(t), where Pₘₐₓ(t) represents the upper limit of the power output of the virtual synchronous generator at the time point t, and Pₘᵢₙ(t) represents the lower limit of the power output of the virtual synchronous generator at the time point t; and finally obtaining the mathematical model for the power output of the virtual synchronous generator.

As a further improvement, the step S500 includes following steps:
S501: accumulating a rated charging power Pess_{j,char_N} of an energy storage device numbered j to obtain a maximum charging power Pess_{char,max}(t) of the virtual energy storage model, and accumulating a rated discharging power Pess_{j,disc_N} of the energy storage device numbered j to obtain a maximum discharging power Pess_{disc,max}(t) of the virtual energy storage module, where Pess_{char,max}(t)=Σⱼ₌₁^{M}Pess_{j,char_N}, Pess_{disc,max}(t)=Σⱼ₌₁^{M}Pess_{j,disc_N}, and M is a positive integer greater than 0;
S502: setting an upper capacity limit of the energy storage device at the time point t to E_{j,max}(t)=Eⱼ(t−1)+Δt×Pess_{j,char_N}, where Eⱼ(t−1) represents an upper capacity limit of the energy storage device at the previous time point, E_{j,max}(t)≤E_{j,max}, and E_{j,max} represents a maximum capacity of the energy storage device; and setting a lower capacity limit of the energy storage device at the time point t to E_{j,min}(t)=Eⱼ(t−1)−Δt×Pess_{j,disc_N}, where E_{j,min}(t)≥E_{j,min}, and E_{j,min} represents a minimum capacity of the energy storage device; and
S503: accumulating upper and lower capacity limits of each energy storage device at the time point t to obtain limit values Eₘₐₓ(t) and Eₘᵢₙ(t) of a total capacity of a virtual energy storage device at the time point t, where Eₘₐₓ(t)=Σⱼ₌₁^{M}E_{j,max}(t), Eₘᵢₙ(t)=Σⱼ₌₁^{M}E_{j,min}(t); and finally obtaining the centralized mathematical model for the capacity of the virtual energy storage model.

As a further improvement, the second-stage aggregation across the distribution transformer areas specifically includes following steps:
S601: constructing an optimal scheduling model for supply-demand interaction within a VPP with an optimization goal of minimizing an internal operating cost of the VPP:

MinJ=Σₜ₌₁^{T}{[(Σₖ₌₁^{K}(Cost_{VS,k}(t)+Cost_{ESS,k}(t))]+Cost_{Grid}(t)}

where Cost_{VS,k}(t) represents an operating cost of a virtual synchronous generator in a k^{th} distribution transformer area; Cost_{ESS,k}(t) represents an operating cost of a virtual energy storage model in the k^{th} distribution transformer area; Cost_{Grid}(t) represents an overall cost of purchasing electricity by the VPP from an external power grid, where a positive value of Cost_{Grid}(t) indicates electricity purchasing, and a negative value of Cost_{Grid}(t) indicates electricity selling; T represents total duration obtained through time point statistics; and K represents a total quantity of distribution transformer areas participating in the aggregation;
S602: obtaining an optimized operating dataset of the VPP based on the optimal scheduling model for supply-demand interaction within the VPP, and storing output powers of each generalized transformer area load model, virtual energy storage model, and virtual synchronous generator in the dataset as preset values;
S603: subtracting an internal total load demand from power outputs of all power generating units within the VPP to obtain a remaining total active power output and a remaining energy storage capacity, calculating inertia and damping coefficients of a virtual synchronous generator with a corresponding active power output capacity based on the remaining total active power output and the remaining energy storage capacity, constructing a mathematical model for the virtual synchronous generator based on the inertia and damping coefficients, taking a total active power output of optimal scheduling models for supply-demand interaction within the VPP that have different capacity levels as an input of the mathematical model for the virtual synchronous generator, and combining the input and an output of the mathematical model for the virtual synchronous generator to form a training dataset;
S604: constructing a deep reinforcement learning model by using a deep Q-learning algorithm, and obtaining, through training, a capacity-adaptive VPP aggregation data model that simulates a characteristic of a real large virtual synchronous generator set; and
S605: uploading the VPP aggregation data model to a cloud-end scheduling platform as a VPP model for the second-stage aggregation.

As a further improvement, the distribution transformer area is a 400 V transformer area that includes a building, a community, a factory, and a school.

A system for implementing the above two-stage self-organizing optimized aggregation method for distributed resources of a VPP includes a distribution transformer area, a first-stage aggregation module, a second-stage aggregation module, an edge computing server, and a cloud end, where the edge computing server is deployed in the distribution transformer area, and the first-stage aggregation module includes a generalized load module, a centralized generator module, and a centralized energy storage module;
the distribution transformer area is provided with a plurality of DERs, the DERs constitute a natural physical cluster that is taken as a first stage, and aggregation is performed by using the edge computing server deployed in the distribution transformer area;
the edge computing server is configured to construct an hourly prediction model for power outputs of wind and solar energy in the entire distribution transformer area and a load curve of the distribution transformer area in the edge computing server based on historical data retrieved from the cloud end and an uncertainty modeling method based on deep Bayesian network learning;
the generalized load module is configured to construct, based on the hourly prediction model, a generalized transformer area load model including wind power, photovoltaic power, and a load;
the centralized generator module is configured to aggregate distributed gas turbines and generators of small hydropower stations in the distribution transformer area into a unified virtual synchronous generator model;
the centralized energy storage module is configured to aggregate distributed energy storage devices in the distribution transformer area into a centralized virtual energy storage model; and
the second-stage aggregation module is configured to upload all parameters of the generalized transformer area load model, the virtual synchronous generator model, and the virtual energy storage model to the cloud end for second-stage aggregation.

A computer device includes a memory and a processor, where the memory stores a computer program; and the processor executes the computer program to implement the steps of the above two-stage self-organizing optimized aggregation method for distributed resources of a VPP.

A computer-readable storage medium stores a computer program thereon, where the computer program is executed by a processor to implement the steps of the above two-stage self-organizing optimized aggregation method for distributed resources of a VPP.

The two-stage self-organizing optimized aggregation method and system for distributed resources of a VPP take a natural physical cluster composed of DERs in a distribution transformer area as a first stage, and perform aggregation by using an edge computing server deployed in the distribution transformer area; perform uncertainty modeling for power outputs of wind and solar energy in the entire distribution transformer area and a load curve of the distribution transformer area in the edge computing server based on historical data retrieved from a cloud end and a deep Bayesian network, and construct an hourly prediction model; construct, based on the hourly prediction model, a generalized transformer area load model including wind power, photovoltaic power, and a load; aggregate distributed gas turbines and generators of small hydropower stations in the distribution transformer area into a unified mathematical model for a power output of a virtual synchronous generator; and finally aggregate distributed energy storage devices in the distribution transformer area into a mathematical model for a capacity of a virtual centralized energy storage device. Upon the above process, first-stage aggregation oriented to the distribution transformer area is completed. Finally, all parameters of the generalized transformer area load model, the virtual synchronous generator model, and the virtual energy storage model are uploaded to the cloud end to complete second-stage aggregation across distribution transformer areas. The present disclosure can fully regulate the DERs in a distribution network and improve energy utilization.

### BRIEF DESCRIPTION OF THE DRAWINGS

The present disclosure is further described by using the accompanying drawings, but the embodiments in the accompanying drawings do not constitute any limitation to the present disclosure. For a person of ordinary skill in the art, other accompanying drawings can be further obtained based on following accompanying drawings without creative efforts.

FIG. 1 is a flowchart of a two-stage self-organizing optimized aggregation method for distributed resources of a VPP; and

FIG. 2 shows a model of a two-stage self-organizing optimized aggregation system for distributed resources of a VPP.

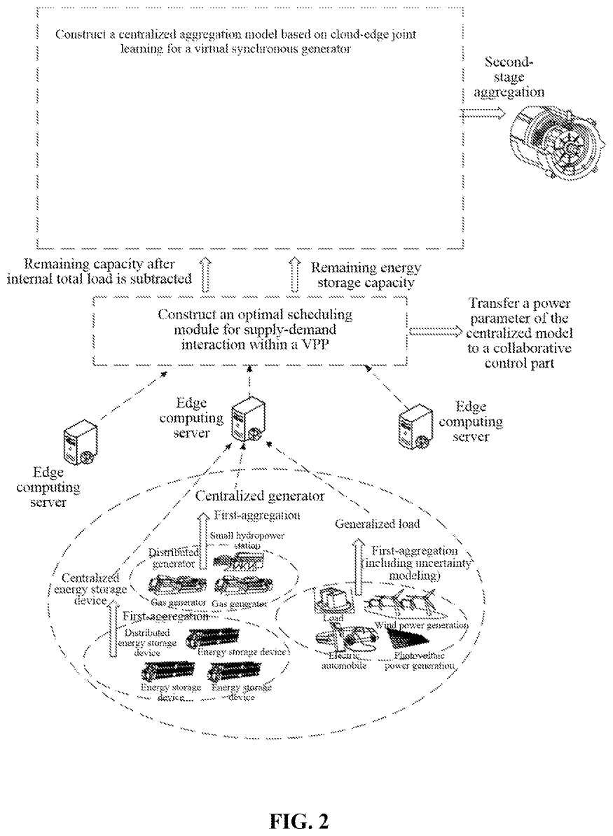

### DETAILED DESCRIPTION OF THE EMBODIMENTS

To enable those skilled in the art to better understand the technical solutions of the present disclosure, the present disclosure will be further described in detail below with reference to the accompanying drawings.

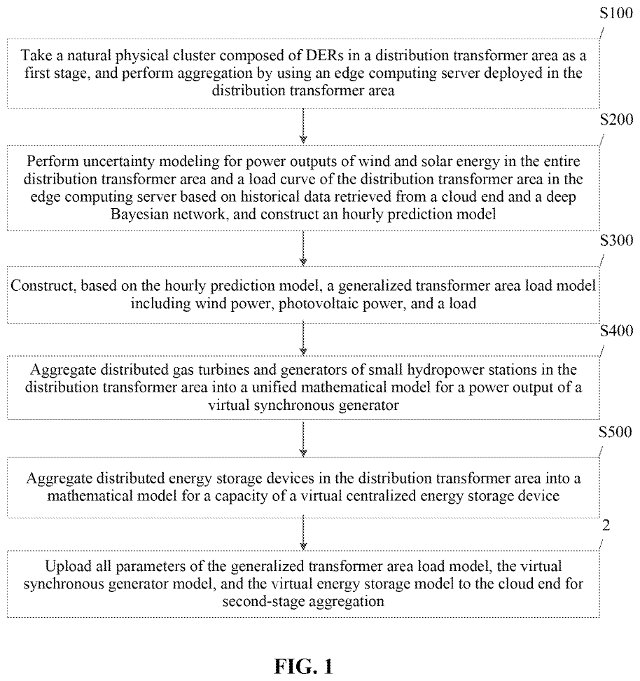

In an embodiment, as shown in FIG. 1, a two-stage self-organizing optimized aggregation method for distributed resources of a VPP includes steps 1) and 2).

1) Conduct first-stage aggregation oriented to a distribution transformer area, which specifically includes steps S100 to S500.

S100: Take a natural physical cluster composed of DERs in the distribution transformer area as a first stage, and perform aggregation by using an edge computing server deployed in the distribution transformer area.

It should be noted that the above distribution transformer area is preferably a 400V distribution transformer area that includes a building, a community, a factory, and a school. The natural physical cluster is a cluster composed of DERs including a distributed photovoltaic source, an energy storage resource, an electric automobile, and a distributed wind generator.

S200: Perform uncertainty modeling for power outputs of wind and solar energy in the entire distribution transformer area and a load curve of the distribution transformer area in the edge computing server based on historical data retrieved from a cloud end and a deep Bayesian network, and construct an hourly prediction model.

Specifically, the historical data includes load baseline data and data of power outputs of wind power generation and photovoltaic power generation.

S300: Construct, based on the hourly prediction model, a generalized transformer area load model including wind power, photovoltaic power, and a load.

S400: Aggregate distributed gas turbines and generators of small hydropower stations in the distribution transformer area into a unified mathematical model for a power output of a virtual synchronous generator.

S500: Aggregate distributed energy storage devices in the distribution transformer area into a mathematical model for a capacity of a virtual centralized energy storage device.

2) Conduct second-stage aggregation across distribution transformer areas: Upload all parameters of the generalized transformer area load model, the virtual synchronous generator model, and the virtual energy storage model to the cloud end for the second-stage aggregation.

Specifically, all the parameters of the virtual energy storage model include a capacity, an active power output, a reactive power output, and inertia and damping coefficients of the virtual synchronous generator.

The present partially implements, based on resource aggregation, self-organizing aggregation of DERs widely distributed in a distribution network, and proposes a two-stage aggregation mode for massive DERs based on geographical distribution characteristics, load densities, power consumption levels, and other factors of the DERs. First, a natural physical cluster composed of DERs in a 400 V distribution transformer area is taken as a first stage, and aggregation is performed by using an edge computing server deployed in the 400 V distribution transformer area. Then, considering randomness of the DERs and load volatility, an hourly prediction model is constructed for power outputs of wind and solar energy in the entire distribution transformer area and a load curve of the distribution transformer area in the edge computing server based on historical data retrieved from a cloud end and an uncertainty modeling method based on deep Bayesian network learning. Based on the hourly prediction model, a generalized transformer area load model including wind power, photovoltaic power, and a load is constructed. After that, distributed gas turbines and generators of small hydropower stations in the distribution transformer area are aggregated into a unified virtual synchronous generator model, and distributed energy storage devices in the distribution transformer area are aggregated into a centralized virtual energy storage model. Upon the above process, first-stage aggregation oriented to the distribution transformer area is completed. Finally, all parameters of the generalized transformer area load model, the virtual synchronous generator model, and the virtual energy storage model are uploaded to the cloud end to complete second-stage aggregation across distribution transformer areas. After the second-stage aggregation, the generalized transformer area load model, the virtual synchronous generator model, and the virtual energy storage model are applied to actual practice to optimize and schedule a real power system. The specific processes are as follows. The cloud-end scheduling platform calculates optimum powers distributed to the generalized transformer area load model, the virtual synchronous generator model, and the virtual energy storage model respectively with a goal of minimizing operating cost of the real power system, according to the uploaded parameters. The optimum powers are decomposed, to obtain powers of the wind power, the photovoltaic power, and the load contained in the generalized transformer area load model, powers of the distributed gas turbines and generators of small hydropower stations contained in the virtual synchronous generator model, and powers of the distributed energy storage devices contained in the virtual energy storage model respectively. With calculated powers as reference powers, charging components and discharging components of the wind power, the photovoltaic power and the load, the distributed gas turbines and generators of small hydropower stations, and the distributed energy storage devices of the real power system are controlled, such that the real power system after controlling can utilize energy reasonably and efficiently. Therefore, the present disclosure can fully regulate the DERs in the distribution network and improve energy utilization.

In an embodiment, the step S400 in which the distributed gas turbines and the generators of the small hydropower stations in the distribution transformer area are aggregated into the unified virtual synchronous generator model includes steps S401 to S403.

S401: Accumulate an upward ramp rate Ramp_{i,up} of a generator numbered i to obtain an upward rate Ramp_{sum,up} of the virtual synchronous generator, and accumulate a downward ramp rate Ramp_{i,down} of the generator numbered i to obtain a downward ramp rate Ramp_{sum,down} of the virtual synchronous generator, where Ramp_{sum,up}=Σᵢ₌₁^{N}Ramp_{i,up}, Ramp_{sum,down}=Σᵢ₌₁^{N}Ramp_{i,down}, and N is a positive integer greater than 0.

S402: Calculate upper and lower limits of a power output of a corresponding virtual synchronous generator at a time point t based on upward and downward ramp rates of each generator, where P_{i,max}(t)=Pᵢ(t−1)+Δt×Ramp_{i,up}, P_{i,min}(t)=Pᵢ(t−1)−Δt×Ramp_{i,down}, P_{i,max}(t)≤P_{i,max}, P_{i,min}(t)≤P_{i,min}, P_{i,max}(t) represents an upper limit of a power output of an i^{th} virtual synchronous generator at the time point t, P_{i,min}(t) represents a lower limit of the power output of the i^{th} virtual synchronous generator at the time point t, Δt represents a time difference between a previous time point and a current time point, Pᵢ(t−1) represents a power output of the virtual synchronous generator at the previous time point, and P_{i,max}, and P_{i,min} respectively represent maximum upper and lower limits of a corresponding power output of the i^{th} virtual synchronous generator.

S403: Accumulate upper and lower limits of a power output of each generator at the time point t to obtain a limit value of a total power output of the corresponding virtual synchronous generator at the time point t, namely, Pₘₐₓ(t)=Σᵢ₌₁^{N}P_{i,max}(t). Pₘᵢₙ(t)=Σᵢ₌₁^{N}P_{i,min}(t), where Pₘₐₓ(t) represents the upper limit of the power output of the virtual synchronous generator at the time point t, and Pₘᵢₙ(t) represents the lower limit of the power output of the virtual synchronous generator at the time point t; and finally obtain the mathematical model for the power output of the virtual synchronous generator.

In an embodiment, the step S500 includes steps S501 to S503.

S501: Accumulate a rated charging power Pess_{j,char_N} of an energy storage device numbered j to obtain a maximum charging power Pess_{char,max}(t) of the virtual energy storage model, and accumulating a rated discharging power Pess_{j,disc_N} of the energy storage device numbered j to obtain a maximum discharging power Pess_{disc,max}(t) of the virtual energy storage module, where Pess_{char,max}(t)=Σⱼ₌₁^{M}Pess_{j,char_N}, Pess_{disc,max}(t)=Σⱼ₌₁^{M}Pess_{j,disc_N}, and M is a positive integer greater than 0.

S502: Set an upper capacity limit of the energy storage device at the time point t to E_{j,max}(t)=Eⱼ(t−1)+Δt×Pess_{j,char_N}, where Eⱼ(t−1) represents an upper capacity limit of the energy storage device at the previous time point, E_{j,max}(t)≤E_{j,max}, and E_{j,max} represents a maximum capacity of the energy storage device; and setting a lower capacity limit of the energy storage device at the time point t to E_{j,min}(t)=Eⱼ(t−1)−Δt×Pess_{j,disc_N}, where E_{j,min}(t)≥E_{j,min}, and E_{j,min} represents a minimum capacity of the energy storage device.

S503: Accumulate upper and lower capacity limits of each energy storage device at the time point t to obtain limit values Eₘₐₓ(t) and Eₘᵢₙ(t) of a total capacity of a virtual energy storage device at the time point t, where Eₘₐₓ(t)=Σⱼ₌₁^{M}E_{j,max}(t), Eₘᵢₙ(t)=Σⱼ₌₁^{M}E_{j,min}(t); and finally obtaining the centralized mathematical model for the capacity of the virtual energy storage model.

In an embodiment, the second-stage aggregation across the distribution transformer areas specifically includes steps S601 to S605.

S601: Construct an optimal scheduling model for supply-demand interaction within a VPP with an optimization goal of minimizing an internal operating cost of the VPP:

MinJ=Σₜ₌₁^{T}{[(Σₖ₌₁^{K}(Cost_{VS,k}(t)+Cost_{ESS,k}(t))]+Cost_{Grid}(t)}

where Cost_{VS,k}(t) represents an operating cost of a virtual synchronous generator in a k distribution transformer area; Cost_{ESS,k}(t) represents an operating cost of a virtual energy storage model in the k^{th} distribution transformer area; Cost_{Grid}(t) represents an overall cost of purchasing electricity by the VPP from an external power grid, where a positive value of Cost_{Grid}(t) indicates electricity purchasing, and a negative value of Cost_{Grid}(t) indicates electricity selling; T represents total duration obtained through time point statistics; and K represents a total quantity of distribution transformer areas participating in the aggregation.

S602: Obtain an optimized operating dataset of the VPP based on the optimal scheduling model for supply-demand interaction within the VPP, and store output powers of each generalized transformer area load model, virtual energy storage model, and virtual synchronous generator in the dataset as preset values.

S603: Subtract an internal total load demand from power outputs of all power generating units within the VPP to obtain a remaining total active power output and a remaining energy storage capacity, calculate inertia and damping coefficients of a virtual synchronous generator with a corresponding active power output capacity based on the remaining total active power output and the remaining energy storage capacity, construct a mathematical model for the virtual synchronous generator based on the inertia and damping coefficients, take a total active power output of optimal scheduling models for supply-demand interaction within the VPP that have different capacity levels as an input of the mathematical model for the virtual synchronous generator, and combine the input and an output of the mathematical model for the virtual synchronous generator to form a training dataset.

Specifically, the power generating units include the gas turbine and the generator of the small hydropower station, and the total load demand is generalized load demand data obtained by adding up the load baseline data and the power outputs of the power outputs of the wind power generation and the photovoltaic power generation.

S604: Construct a deep reinforcement learning model by using a deep Q-learning algorithm, and obtain, through training, a capacity-adaptive VPP aggregation data model that simulates a characteristic of a real large virtual synchronous generator set.

S605: Upload the VPP aggregation data model to a cloud-end scheduling platform as a VPP model for the second-stage aggregation.

In conclusion, the present disclosure well regulates the DERs in a distribution network through two-stage aggregation, and achieves high energy utilization.

In an embodiment, a computer device is provided, including a memory and a processor, where the memory stores a computer program, and the computer program is executed by the processor to implement the steps of the two-stage self-organizing optimized aggregation method for distributed resources of a VPP.

In an embodiment, a computer-readable storage medium is provided, where the computer-readable storage medium stores a computer program, and the computer program is executed by a processor to implement the steps of the two-stage self-organizing optimized aggregation method for distributed resources of a VPP.

Those skilled in the art should understand that the embodiments of the present disclosure may be provided as a method, a system, or a computer program product. Therefore, the present disclosure may use a form of hardware only embodiments, software only embodiments, or embodiments with a combination of software and hardware. Moreover, the present disclosure may use a form of a computer program product that is implemented on one or more computer-readable storage media (including but not limited to a disk memory, a CD-ROM, an optical memory, and the like) that include computer-usable program code. The present disclosure is described with reference to the flowcharts and/or block diagrams of the method, the device (system), and the computer program product according to the embodiments of the present disclosure. It should be understood that computer program instructions may be used to implement each process and/or each block in the flowcharts and/or the block diagrams and a combination of a process and/or a block in the flowcharts and/or the block diagrams. These computer program instructions may be provided for a general-purpose computer, a dedicated computer, an embedded processor, or a processor of another programmable data processing device to generate a machine, such that the instructions executed by a computer or a processor of another programmable data processing device generate an apparatus for implementing a specific function in one or more processes in the flowcharts and/or in one or more blocks in the block diagrams. These computer program instructions may be stored in a computer-readable memory that can instruct a computer or another programmable data processing device to work in a specific manner, such that the instructions stored in the computer-readable memory generate an artifact that includes an instruction apparatus. The instruction apparatus implements a specific function in one or more processes in the flowcharts and/or in one or more blocks in the block diagrams. These computer program instructions may be loaded onto a computer or another programmable data processing device, such that a series of operations and steps are performed on the computer or the another programmable device, thereby generating computer-implemented processing. Therefore, the instructions executed on the computer or the another programmable device provide steps for implementing a specific function in one or more processes in the flowcharts and/or in one or more blocks in the block diagrams.

The above describes in detail the two-stage self-organization optimized aggregation method and system for distributed resources of a VPP in the present disclosure. Specific cases are used herein to illustrate the principle and implementation of the present disclosure, and the description of the above embodiments is only intended to help understand the core idea of the present disclosure. It should be noted that several improvements and modifications may be made by persons of ordinary skill in the art without departing from the principle of the present disclosure, and these improvements and modifications should also fall within the protection scope of the present disclosure.

1. A two-stage self-organizing optimized aggregation method for distributed resources of a virtual power plant (VPP), comprising following steps:
1) conducting first-stage aggregation oriented to a distribution transformer area, which comprises following steps:
S100: taking a natural physical cluster composed of distributed energy resources (DERs) in the distribution transformer area as a first stage, and performing aggregation by using an edge computing server deployed in the distribution transformer area;
S200: performing uncertainty modeling for power outputs of wind and solar energy in the entire distribution transformer area and a load curve of the distribution transformer area in the edge computing server based on historical data retrieved from a cloud end and a deep Bayesian network, and constructing an hourly prediction model;
S300: constructing, based on the hourly prediction model, a generalized transformer area load model comprising wind power, photovoltaic power, and a load;
S400: aggregating distributed gas turbines and generators of small hydropower stations in the distribution transformer area into a unified mathematical model for a power output of a virtual synchronous generator; and
S500: aggregating distributed energy storage devices in the distribution transformer area into a mathematical model for a capacity of a virtual centralized energy storage device; and
2) conducting second-stage aggregation across distribution transformer areas: uploading all parameters of the generalized transformer area load model, the virtual synchronous generator model, and the virtual energy storage model to the cloud end for the second-stage aggregation;
wherein, in a scheduling platform of the cloud end, optimum powers distributed to the generalized transformer area load model, the virtual synchronous generator model, and the virtual energy storage model are calculated according to the all parameters uploaded, with a goal of minimizing operating cost of a target power system the optimum powers is decomposed, to obtain powers of the wind power, the photovoltaic power, and the load, powers of the distributed gas turbines and the generators of small hydropower stations, and powers of the distributed energy storage devices, respectively; charging components and discharging components in the wind power, the photovoltaic power and the load, the distributed gas turbines and the generators of small hydropower stations, and the distributed energy storage devices of the target power system are controlled according to the powers decomposed.

2. The two-stage self-organizing optimized aggregation method for distributed resources of a VPP according to claim 1, wherein the step S400 comprises following steps:
S401: accumulating an upward ramp rate Ramp_{i,up} of a generator numbered i to obtain an upward rate Ramp_{sum,up} of the virtual synchronous generator, and accumulating a downward ramp rate Ramp_{i,down} of the generator numbered i to obtain a downward ramp rate Ramp_{sum,down} of the virtual synchronous generator, where Ramp_{sum,up}=Σᵢ₌₁^{N}Ramp_{i,up}, Ramp_{sum,down}=Σᵢ₌₁^{N}Ramp_{i,down}, and N is a positive integer greater than 0;
S402: calculating upper and lower limits of a power output of a corresponding virtual synchronous generator at a time point t based on upward and downward ramp rates of each generator, where P_{i,max}(t)=Pᵢ(t−1)+Δt×Rampᵢₘₚ, P_{i,min}(t)=Pᵢ(t−1)−Δt×Ramp_{i,down}, P_{i,max}(t)≤P_{i,max}, P_{i,min}(t)≤P_{i,min}, P_{i,max}(t) represents an upper limit of a power output of an i^{th} virtual synchronous generator at the time point t, P_{i,min}(t) represents a lower limit of the power output of the i^{th} virtual synchronous generator at the time point t, Δt represents a time difference between a previous time point and a current time point, Pᵢ(t−1) represents a power output of the virtual synchronous generator at the previous time point, and P_{i,max} and P_{i,min} respectively represent maximum upper and lower limits of a corresponding power output of the i^{th} virtual synchronous generator; and
S403: accumulating upper and lower limits of a power output of each generator at the time point t to obtain a limit value of a total power output of the corresponding virtual synchronous generator at the time point t, namely, Pₘₐₓ(t)=Σᵢ₌₁^{N}P_{i,max}(t), Pₘᵢₙ(t)=Σᵢ₌₁^{N}P_{i,min}(t), wherein Pₘₐₓ(t) represents the upper limit of the power output of the virtual synchronous generator at the time point t, and Pₘᵢₙ(t) represents the lower limit of the power output of the virtual synchronous generator at the time point t; and finally obtaining the mathematical model for the power output of the virtual synchronous generator.

3. The two-stage self-organizing optimized aggregation method for distributed resources of a VPP according to claim 2, wherein the step S500 comprises following steps:
S501: accumulating a rated charging power Pess_{j,char_N} of an energy storage device numbered j to obtain a maximum charging power Pess_{char,max}(t) of the virtual energy storage model, and accumulating a rated discharging power Pess_{j,disc_N} of the energy storage device numbered j to obtain a maximum discharging power Pess_{disc,max}(t) of the virtual energy storage module, where Pess_{char,max}(t)=Σⱼ₌₁^{M}Pess_{j,char_N}, Pess_{disc,max}(t)=Σⱼ₌₁^{M}Pess_{j,disc_N}, and M is a positive integer greater than 0;
S502: setting an upper capacity limit of the energy storage device at the time point t to E_{j,max}(t)=Eⱼ(t−1)+Δt×Pess_{j,char_N}, where Eⱼ(t−1) represents an upper capacity limit of the energy storage device at the previous time point, E_{j,max}(t)≤E_{j,max}, and E_{j,max} represents a maximum capacity of the energy storage device; and setting a lower capacity limit of the energy storage device at the time point t to E_{j,min}(t)=Eⱼ(t−1)−Δt×Pess_{j,disc_N}, where E_{j,min}(t)≥E_{j,min}, and E_{j,min} represents a minimum capacity of the energy storage device; and
S503: accumulating upper and lower capacity limits of each energy storage device at the time point t to obtain limit values Eₘₐₓ(t) and Eₘᵢₙ(t) of a total capacity of a virtual energy storage device at the time point t, where Eₘₐₓ(t)=Σⱼ₌₁^{M}E_{j,max}(t), Eₘᵢₙ(t)=Σⱼ₌₁^{M}E_{j,min}(t); and finally obtaining the centralized mathematical model for the capacity of the virtual energy storage model.

4. The two-stage self-organizing optimized aggregation method for distributed resources of a VPP according to claim 3, wherein the second-stage aggregation across the distribution transformer areas comprises following steps:
S601: constructing an optimal scheduling model for supply-demand interaction within a VPP with an optimization goal of minimizing an internal operating cost of the VPP:
MinJ=Σₜ₌₁^{T}{[(Σₖ₌₁^{K}(Cost_{VS,k}(t)+Cost_{ESS,k}(t))]+Cost_{Grid}(t)}
where Cost_{VS,k}(t) represents an operating cost of a virtual synchronous generator in a k^{th} distribution transformer area; Cost_{ESS,k}(t) represents an operating cost of a virtual energy storage model in the k^{th} distribution transformer area; Cost_{Grid}(t) represents an overall cost of purchasing electricity by the VPP from an external power grid, where a positive value of Cost_{Grid}(t) indicates electricity purchasing, and a negative value of Cost_{Grid}(t) indicates electricity selling; T represents total duration obtained through time point statistics; and K represents a total quantity of distribution transformer areas participating in the aggregation;
S602: obtaining an optimized operating dataset of the VPP based on the optimal scheduling model for supply-demand interaction within the VPP, and storing output powers of each generalized transformer area load model, virtual energy storage model, and virtual synchronous generator in the dataset as preset values;
S603: subtracting an internal total load demand from power outputs of all power generating units within the VPP to obtain a remaining total active power output and a remaining energy storage capacity, calculating inertia and damping coefficients of a virtual synchronous generator with a corresponding active power output capacity based on the remaining total active power output and the remaining energy storage capacity, constructing a mathematical model for the virtual synchronous generator based on the inertia and damping coefficients, taking a total active power output of optimal scheduling models for supply-demand interaction within the VPP that have different capacity levels as an input of the mathematical model for the virtual synchronous generator, and combining the input and an output of the mathematical model for the virtual synchronous generator to form a training dataset;
S604: constructing a deep reinforcement learning model by using a deep Q-learning algorithm, and obtaining, through training, a capacity-adaptive VPP aggregation data model that simulates a characteristic of a real large virtual synchronous generator set; and
S605: uploading the VPP aggregation data model to a cloud-end scheduling platform as a VPP model for the second-stage aggregation.

5. The two-stage self-organizing optimized aggregation method for distributed resources of a VPP according to claim 4, wherein the distribution transformer area is a 400 V transformer area that comprises a building, a community, a factory, and a school.

6. A system for implementing the two-stage self-organizing optimized aggregation method for distributed resources of a VPP according to claim 1, wherein the system comprises a distribution transformer area, a first-stage aggregation module, a second-stage aggregation module, an edge computing server, and a cloud end, wherein the edge computing server is deployed in the distribution transformer area, and the first-stage aggregation module comprises a generalized load module, a centralized generator module, and a centralized energy storage module;
the distribution transformer area is provided with a plurality of DERs, the DERs constitute a natural physical cluster that is taken as a first stage, and aggregation is performed by using the edge computing server deployed in the distribution transformer area;
the edge computing server is configured to construct an hourly prediction model for power outputs of wind and solar energy in the entire distribution transformer area and a load curve of the distribution transformer area in the edge computing server based on historical data retrieved from the cloud end and an uncertainty modeling method based on deep Bayesian network learning;
the generalized load module is configured to construct, based on the hourly prediction model, a generalized transformer area load model comprising wind power, photovoltaic power, and a load;
the centralized generator module is configured to aggregate distributed gas turbines and generators of small hydropower stations in the distribution transformer area into a unified virtual synchronous generator model;
the centralized energy storage module is configured to aggregate distributed energy storage devices in the distribution transformer area into a centralized virtual energy storage model; and
the second-stage aggregation module is configured to upload all parameters of the generalized transformer area load model, the virtual synchronous generator model, and the virtual energy storage model to the cloud end for second-stage aggregation;
wherein, in a scheduling platform of the cloud end, optimum powers distributed to the generalized transformer area load model, the virtual synchronous generator model, and the virtual energy storage model are calculated according to the all parameters uploaded, with a goal of minimizing operating cost of a target power system; the optimum powers is decomposed to obtain powers of the wind power, the photovoltaic power, and the load, powers of the distributed gas turbines and the generators of small hydropower stations, and powers of the distributed energy storage devices, respectively; charging components and discharging components in the wind power, the photovoltaic power and the load, the distributed gas turbines and the generators of small hydropower stations, and the distributed energy storage devices of the target power system are controlled according to the powers decomposed.

7. (canceled)

8. A computer-readable storage medium, wherein the computer-readable storage medium stores a computer program, and the computer program is executed by a processor to implement the steps of the two-stage self-organizing optimized aggregation method for distributed resources of a VPP according to claim 1.

9. The system according to claim 6, wherein the step S400 comprises following steps:
S401: accumulating an upward ramp rate Ramp_{i,up} of a generator numbered i to obtain an upward rate Ramp_{sum,up} of the virtual synchronous generator, and accumulating a downward ramp rate Ramp_{i,down} of the generator numbered i to obtain a downward ramp rate Ramp_{sum,down} of the virtual synchronous generator, where Ramp_{sum,up}=Σᵢ₌₁^{N}Ramp_{i,up}, Ramp_{sum,down}=Σᵢ₌₁^{N}Ramp_{i,down}, and N is a positive integer greater than 0;
S402: calculating upper and lower limits of a power output of a corresponding virtual synchronous generator at a time point t based on upward and downward ramp rates of each generator, where P_{i,max}(t)=Pᵢ(t−1)+Δt×Rampᵢₘₚ, P_{i,min}(t)=Pᵢ(t−1)−Δt×Ramp_{i,down}, P_{i,max}(t)≤P_{i,max}, P_{i,min}(t)≤P_{i,min}, P_{i,max}(t) represents an upper limit of a power output of an i^{th} virtual synchronous generator at the time point t, P_{i,min}(t) represents a lower limit of the power output of the i^{th} virtual synchronous generator at the time point t, Δt represents a time difference between a previous time point and a current time point, Pᵢ(t−1) represents a power output of the virtual synchronous generator at the previous time point, and P_{i,max} and P_{i,min} respectively represent maximum upper and lower limits of a corresponding power output of the i^{th} virtual synchronous generator; and
S403: accumulating upper and lower limits of a power output of each generator at the time point t to obtain a limit value of a total power output of the corresponding virtual synchronous generator at the time point t, namely, Pₘₐₓ(t)=Σᵢ₌₁^{N}P_{i,max}(t), Pₘᵢₙ(t)=Σᵢ₌₁^{N}P_{i,min}(t), wherein Pₘₐₓ(t) represents the upper limit of the power output of the virtual synchronous generator at the time point t, and Pₘᵢₙ(t) represents the lower limit of the power output of the virtual synchronous generator at the time point t; and finally obtaining the mathematical model for the power output of the virtual synchronous generator.

10. The system according to claim 9, wherein the step S500 comprises following steps:
S501: accumulating a rated charging power Pess_{j,char_N} of an energy storage device numbered j to obtain a maximum charging power Pess_{char,max}(t) of the virtual energy storage model, and accumulating a rated discharging power Pess_{j,disc_N} of the energy storage device numbered j to obtain a maximum discharging power Pess_{disc,max}(t) of the virtual energy storage module, where Pess_{char,max}(t)=Σⱼ₌₁^{M}Pess_{j,char_N}, Pess_{disc,max}(t)=Σⱼ₌₁^{M}Pess_{j,disc_N}, and M is a positive integer greater than 0;
S502: setting an upper capacity limit of the energy storage device at the time point t to E_{j,max}(t)=Eⱼ(t−1)+Δt×Pess_{j,char_N}, where Eⱼ(t−1) represents an upper capacity limit of the energy storage device at the previous time point, E_{j,max}(t)≤E_{j,max}, and E_{j,max} represents a maximum capacity of the energy storage device; and setting a lower capacity limit of the energy storage device at the time point t to E_{j,min}(t)=Eⱼ(t−1)−Δt×Pess_{j,disc_N}, where E_{j,min}(t)≥E_{j,min}, and E_{j,min} represents a minimum capacity of the energy storage device; and
S503: accumulating upper and lower capacity limits of each energy storage device at the time point t to obtain limit values Eₘₐₓ(t) and Eₘᵢₙ(t) of a total capacity of a virtual energy storage device at the time point t, where Eₘₐₓ(t)=Σⱼ₌₁^{M}E_{j,max}(t), Eₘᵢₙ(t)=Σⱼ₌₁^{M}E_{j,min}(t); and finally obtaining the centralized mathematical model for the capacity of the virtual energy storage model.

11. The system according to claim 10, wherein the second-stage aggregation across the distribution transformer areas comprises following steps:
S601: constructing an optimal scheduling model for supply-demand interaction within a VPP with an optimization goal of minimizing an internal operating cost of the VPP:
MinJ=Σₜ₌₁^{T}{[(Σₖ₌₁^{K}(Cost_{VS,k}(t)+Cost_{ESS,k}(t))]+Cost_{Grid}(t)}
where Cost_{VS,k}(t) represents an operating cost of a virtual synchronous generator in a k^{th} distribution transformer area; Cost_{ESS,k}(t) represents an operating cost of a virtual energy storage model in the k^{th} distribution transformer area; Cost_{Grid}(t) represents an overall cost of purchasing electricity by the VPP from an external power grid, where a positive value of Cost_{Grid}(t) indicates electricity purchasing, and a negative value of Cost_{Grid}(t) indicates electricity selling; T represents total duration obtained through time point statistics; and K represents a total quantity of distribution transformer areas participating in the aggregation;
S602: obtaining an optimized operating dataset of the VPP based on the optimal scheduling model for supply-demand interaction within the VPP, and storing output powers of each generalized transformer area load model, virtual energy storage model, and virtual synchronous generator in the dataset as preset values;
S603: subtracting an internal total load demand from power outputs of all power generating units within the VPP to obtain a remaining total active power output and a remaining energy storage capacity, calculating inertia and damping coefficients of a virtual synchronous generator with a corresponding active power output capacity based on the remaining total active power output and the remaining energy storage capacity, constructing a mathematical model for the virtual synchronous generator based on the inertia and damping coefficients, taking a total active power output of optimal scheduling models for supply-demand interaction within the VPP that have different capacity levels as an input of the mathematical model for the virtual synchronous generator, and combining the input and an output of the mathematical model for the virtual synchronous generator to form a training dataset;
S604: constructing a deep reinforcement learning model by using a deep Q-learning algorithm, and obtaining, through training, a capacity-adaptive VPP aggregation data model that simulates a characteristic of a real large virtual synchronous generator set; and
S605: uploading the VPP aggregation data model to a cloud-end scheduling platform as a VPP model for the second-stage aggregation.

12. The system according to claim 11, wherein the distribution transformer area is a 400 V transformer area that comprises a building, a community, a factory, and a school.

13. The computer-readable storage medium according to claim 8, wherein the step S400 comprises following steps:
S401: accumulating an upward ramp rate Ramp_{i,up} of a generator numbered i to obtain an upward rate Ramp_{sum,up} of the virtual synchronous generator, and accumulating a downward ramp rate Ramp_{i,down} of the generator numbered i to obtain a downward ramp rate Ramp_{sum,down} of the virtual synchronous generator, where Ramp_{sum,up}=Σᵢ₌₁^{N}Ramp_{i,up}, Ramp_{sum,down}=Σᵢ₌₁^{N}Ramp_{i,down}, and N is a positive integer greater than 0;
S402: calculating upper and lower limits of a power output of a corresponding virtual synchronous generator at a time point t based on upward and downward ramp rates of each generator, where P_{i,max}(t)=Pᵢ(t−1)+Δt×Rampᵢₘₚ, P_{i,min}(t)=Pᵢ(t−1)−Δt×Ramp_{i,down}, P_{i,max}(t)≤P_{i,max}, P_{i,min}(t)≤P_{i,min}, P_{i,max}(t) represents an upper limit of a power output of an i^{th} virtual synchronous generator at the time point t, P_{i,min}(t) represents a lower limit of the power output of the i^{th} virtual synchronous generator at the time point t, Δt represents a time difference between a previous time point and a current time point, Pᵢ(t−1) represents a power output of the virtual synchronous generator at the previous time point, and P_{i,max} and P_{i,min} respectively represent maximum upper and lower limits of a corresponding power output of the i^{th} virtual synchronous generator; and
S403: accumulating upper and lower limits of a power output of each generator at the time point t to obtain a limit value of a total power output of the corresponding virtual synchronous generator at the time point t, namely, Pₘₐₓ(t)=Σᵢ₌₁^{N}P_{i,max}(t), Pₘᵢₙ(t)=Σᵢ₌₁^{N}P_{i,min}(t), wherein Pₘₐₓ(t) represents the upper limit of the power output of the virtual synchronous generator at the time point t, and Pₘᵢₙ(t) represents the lower limit of the power output of the virtual synchronous generator at the time point t; and finally obtaining the mathematical model for the power output of the virtual synchronous generator.

14. The computer-readable storage medium according to claim 13, wherein the step S500 comprises following steps:
S501: accumulating a rated charging power Pess_{j,char_N} of an energy storage device numbered j to obtain a maximum charging power Pess_{char,max}(t) of the virtual energy storage model, and accumulating a rated discharging power Pess_{j,disc_N} of the energy storage device numbered j to obtain a maximum discharging power Pess_{disc,max}(t) of the virtual energy storage module, where Pess_{char,max}(t)=Σⱼ₌₁^{M}Pess_{j,char_N}, Pess_{disc,max}(t)=Σⱼ₌₁^{M}Pess_{j,disc_N}, and M is a positive integer greater than 0;
S502: setting an upper capacity limit of the energy storage device at the time point t to E_{j,max}(t)=Eⱼ(t−1)+Δt×Pess_{j,char_N}, where Eⱼ(t−1) represents an upper capacity limit of the energy storage device at the previous time point, E_{j,max}(t)≤E_{j,max}, and E_{j,max} represents a maximum capacity of the energy storage device; and setting a lower capacity limit of the energy storage device at the time point t to E_{j,min}(t)=Eⱼ(t−1)−Δt×Pess_{j,disc_N}, where E_{j,min}(t)≥E_{j,min}, and E_{j,min} represents a minimum capacity of the energy storage device; and
S503: accumulating upper and lower capacity limits of each energy storage device at the time point t to obtain limit values Eₘₐₓ(t) and Eₘᵢₙ(t) of a total capacity of a virtual energy storage device at the time point t, where Eₘₐₓ(t)=Σⱼ₌₁^{M}E_{j,max}(t), Eₘᵢₙ(t)=Σⱼ₌₁^{M}E_{j,min}(t); and finally obtaining the centralized mathematical model for the capacity of the virtual energy storage model.

15. The computer-readable storage medium according to claim 14, wherein the second-stage aggregation across the distribution transformer areas comprises following steps:
S601: constructing an optimal scheduling model for supply-demand interaction within a VPP with an optimization goal of minimizing an internal operating cost of the VPP:
MinJ=Σₜ₌₁^{T}{[(Σₖ₌₁^{K}(Cost_{VS,k}(t)+Cost_{ESS,k}(t))]+Cost_{Grid}(t)}
where Cost_{VS,k}(t) represents an operating cost of a virtual synchronous generator in a k^{th} distribution transformer area; Cost_{ESS,k}(t) represents an operating cost of a virtual energy storage model in the k^{th} distribution transformer area; Cost_{Grid}(t) represents an overall cost of purchasing electricity by the VPP from an external power grid, where a positive value of Cost_{Grid}(t) indicates electricity purchasing, and a negative value of Cost_{Grid}(t) indicates electricity selling; T represents total duration obtained through time point statistics; and K represents a total quantity of distribution transformer areas participating in the aggregation;
S602: obtaining an optimized operating dataset of the VPP based on the optimal scheduling model for supply-demand interaction within the VPP, and storing output powers of each generalized transformer area load model, virtual energy storage model, and virtual synchronous generator in the dataset as preset values;
S603: subtracting an internal total load demand from power outputs of all power generating units within the VPP to obtain a remaining total active power output and a remaining energy storage capacity, calculating inertia and damping coefficients of a virtual synchronous generator with a corresponding active power output capacity based on the remaining total active power output and the remaining energy storage capacity, constructing a mathematical model for the virtual synchronous generator based on the inertia and damping coefficients, taking a total active power output of optimal scheduling models for supply-demand interaction within the VPP that have different capacity levels as an input of the mathematical model for the virtual synchronous generator, and combining the input and an output of the mathematical model for the virtual synchronous generator to form a training dataset;
S604: constructing a deep reinforcement learning model by using a deep Q-learning algorithm, and obtaining, through training, a capacity-adaptive VPP aggregation data model that simulates a characteristic of a real large virtual synchronous generator set; and
S605: uploading the VPP aggregation data model to a cloud-end scheduling platform as a VPP model for the second-stage aggregation.

16. The computer-readable storage medium according to claim 15, wherein the distribution transformer area is a 400 V transformer area that comprises a building, a community, a factory, and a school.
